(19) United States
(12) Patent Application Publication
(10) Pub. No.: US 2007/0093069 A1
(43) Pub. Date: Apr. 26, 2007

(54) PURGE PROCESS AFTER DRY ETCHING

(76) Inventors: Chien-Hua Tsai, Taichung City (TW); Yi-Chin Wu, Kaohsiung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,510

(22) Filed: Oct. 21, 2005

(51) Int. Cl. H01L 21/311; H01L 21/302; H01L 21/461

(52) U.S. Cl. 438/710; 438/700; 438/706

(57) ABSTRACT

A purge process for a chip performed after a dry etching process is provided. The dry etching process is carried out inside a reaction chamber. The purge process is used to remove any byproducts produced by said dry etching process. The purge process includes injecting an inert gas into the reaction chamber to purge the same. Then, the gas inside the reaction chamber is exhausted. The purge process prevents the formation of defects in subsequent metal interconnect fabrication process.

### BACKGROUND OF THE INVENTION

1. Field of the Invention

The present invention relates to a method of purging an integrated circuit device. More particularly, the present invention relates to a purge process performed after a dry etching process.

2. Description of the Related Art

The processes used for etching out semiconductor devices mainly include wet etching and dry etching. The former etching process mainly uses a chemical reaction to achieve the etching of a thin film while the later etching process mainly uses a physical action to achieve the etching the same. However, as the semiconductor process develops to the sub-micron generation and the size of a wafer reaches 12 inches diameter, the uniformity and etching rate of a product have become critical factors. Because dry etching is an anisotropic etching technique and has the advantage of a better control of the profile of a thin film after the etching process, it has become a mainstream etching process for manufacturing semiconductor devices.

However, the plasma reactive gases of dry etching will react with the material on the surface of the wafer and generate some byproducts. For example, the plasma for etching back tungsten plug is a fluorine-containing (F) gas. The fluorine element within the gas may react with the titanium nitride (TiN) adhesion layer on the surface of the chip to form titanium fluoride (TiₓF_{y}). Titanium fluoride (TiₓF_{y}) will react with moisture in the air to form titanium-fluorine oxide (TiₓF_{y}O_{z}). The byproduct such as the titanium-fluorine oxide (TiₓF_{y}O_{z}) often leads to some defects in the subsequently formed metal interconnects, for example, bridge problem, that may reduce the yield and reliability of the wafer.

In general, the problem of having byproducts after a dry etching process more readily occur in the process of fabricating metal interconnects. For example, in the dual damascene process for forming openings of conductive lines and plugs (dual damascene openings), high molecular weight residues or metal oxide material is easily produced. Therefore, there is a need to purge away these byproducts effectively.

### SUMMARY OF THE INVENTION

Accordingly, at least one objective of the present invention is to provide a purge process suitable for removing byproducts formed on a wafer after a dry etching process.

At least another objective of the present invention is to provide a method of forming a dual damascene opening capable of preventing a metal interconnect patterning process from error.

At least yet another objective of the present invention is to provide a method of forming a dual damascene opening capable of removing the byproducts of an etching process.

To achieve these and other advantages and in accordance with the purpose of the invention, as embodied and broadly described herein, the invention provides a purge process after a dry etching process. The dry etching of a wafer is carried out within a reaction chamber. The purge process includes: a) channeling an inert gas into the reaction chamber to purge the same, and b) exhausting all the gases within the reaction chamber. Furthermore, step (a) or step (b) can be carried out first and step (a) and step (b) can be repeated to remove the byproducts caused by the dry etching process.

In one embodiment, the inert gas includes nitrogen or helium, for example.

In one embodiment, the aforementioned purge process may further includes bombarding the wafer with inert gas plasma. The inert gas plasma is argon plasma, for example.

The present invention also provides a method of forming a dual damascene opening. The method includes providing a substrate and forming a dielectric layer and a hard mask layer on the substrate, sequentially. Then, a trench pattern is formed by performing a dry etching process to the hard mask layer inside a first reaction chamber. After that, a first purging process is carried out. The first purging process includes: a) channeling a first inert gas into the first reaction chamber to purge the same, and b) exhausting all the first inert gas inside the first reaction chamber. Step (a) or step (b) can be carried out first and step (a) and step (b) can be repeated to entirely remove the byproducts caused by the dry etching process. Thereafter, a patterned photoresist layer is formed on the substrate, and the patterned photoresist layer has a via opening pattern. Then, another dry etching process is performed to the dielectric layer inside a second reaction chamber by using the patterned photoresist layer as a mask, thereby removing the dielectric layer exposed by the via opening pattern and forming a via opening. Subsequently, the patterned photoresist layer is removed, and then a second purge process is carried out. The second purge process includes: c) channeling a second inert gas into the second reaction chamber to purge the same, and d) exhausting all the gas inside the second reaction chamber. Step (c) or step (d) can be carried out first and step (c) and step (d) can be repeated to completely remove the byproducts caused by the dry etching process. After that, another dry etching process is carried out to the dielectric layer inside a third reaction chamber by utilizing the hard mask layer as a mask, thereby removing portion of the dielectric layer exposed by the trench pattern and forming a trench on the via opening. Then, a third purge process is carried out. The third purge process includes: e) channeling a third inert gas into a third reaction chamber to purge the same, and f) exhausting all the gas inside the third reaction chamber. Step (e) or step (f) can be carried out first and step (e) and step (f) can be repeated to wholly remove the byproducts formed by the dry etching process.

In one embodiment, the first, the second and/or the third inert gas include nitrogen or helium, for example. In one embodiment, the first, the second and/or the third purge process may further include bombarding the substrate with an inert gas plasma. The inert gas plasma is argon plasma, for example.

In one embodiment, the hard mask layer is a metal hard mask layer. The metal hard mask layer is made of titanium, titanium nitride, tantalum, tantalum nitride or tungsten nitride, for example.

In one embodiment, after forming the hard mask layer but before forming the trench pattern, the method further includes forming an anti-reflection layer on the hard mask layer. The anti-reflection layer is made of silicon oxynitride, for example.

The present invention also provides an alternative method of forming a dual damascene opening. The method includes providing a substrate and forming a dielectric layer and a hard mask layer on the substrate, sequentially. Then, a trench pattern is formed through a dry etching process that is performed to the hard mask layer in a first reaction chamber. Then, a first purge process is carried out. The first purge process includes: a) channeling a first inert gas into the first reaction chamber to purge the same, and b) exhausting all the gas inside the first reaction chamber. Step (a) or step (b) can be carried out first and step (a) and step (b) can be repeated to entirely remove the byproducts formed from the dry etching process. Thereafter, another dry etching process is carried out to the dielectric layer in a second reaction chamber by utilizing the hard mask layer as a mask, thereby removing the dielectric layer exposed by the trench pattern and forming a trench. Then, a second purge process is carried out. The second purge process includes: c) channeling a second inert gas into a second reaction chamber to purge the same, and d) exhausting all the gas inside the second reaction chamber. Step (c) or step (d) can be carried out first and step (c) and step (d) can be repeated to wholly remove the byproducts caused by the dry etching process. Then, a patterned photoresist layer is formed on the substrate, and the patterned photoresist layer has a via opening pattern that formed inside the trench. Thereafter, another dry etching process is performed to the dielectric layer inside a third reaction chamber by using the patterned photoresist layer as a mask, thereby removing the dielectric layer exposed by the via opening pattern and forming a via opening. Subsequently, the patterned photoresist layer is removed, and then a third purge process is carried out. The third purge process includes: e) channeling a third inert gas into a third reaction chamber to purge the same, and f) exhausting all the gas inside the third reaction chamber. Step (e) or step (f) can be carried out first and step (e) and step (f) can be repeated to completely remove the byproducts formed from the dry etching process.

In one embodiment, the first, the second and/or the third inert gas is nitrogen or helium, for example. In one embodiment, the first, the second and/or the third purge process may further include bombarding the substrate with inert gas plasma. The inert gas plasma is argon plasma, for example.

In one embodiment, the hard mask layer is a metal hard mask layer. The metal hard mask layer is fabricated using titanium, titanium nitride, tantalum, tantalum nitride or tungsten nitride, for example.

In one embodiment, after forming the hard mask layer but before formng the trench pattern, the method further includes forming an anti-reflection layer on the hard mask layer. The anti-reflection layer is fabricated using silicon oxynitride, for example.

The purge process according to the present application can effectively remove the byproducts caused by the dry etching process, and thus it can keep the electric property of the subsequently formed structure. Besides, there is no chemical reaction in the purge process of the present application, so it is unable to change the profile of the pattern caused by the dry etching process. Moreover, the purge process in the present invention can prevent the byproducts caused by an etching process from remaining inside the dual damascene opening leading to the non-uniformity of electrical properties in the subsequently formed metal interconnects. Hence, a drop in the yield is prevented.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow diagram showing the steps of a purge process according to the present invention.

FIGS. 2A to 2E are schematic cross-sectional views showing the process of forming a dual damascene opening according to one embodiment of the present invention.

FIGS. 3A to 3E are schematic cross-sectional views showing the process of forming a dual damascene opening according to another embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

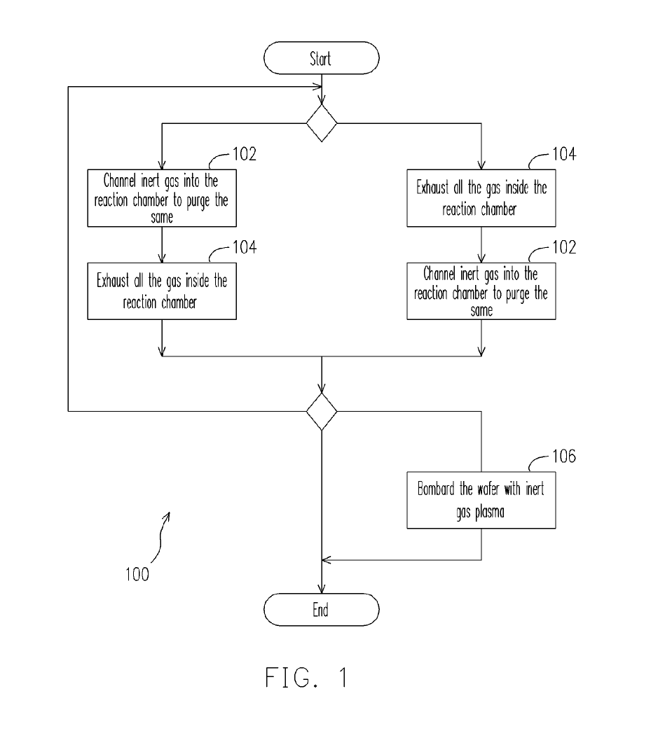

FIG. 1 is a flow diagram showing the steps of a purge process according to the present invention. As shown in FIG. 1, the purge process 100 of the present invention is for a wafer after a dry etching process. The dry etching process is carried out in a reaction chamber, and the purge process 100 is utilized to remove the byproducts caused by the dry etching process. After the dry etching process is performed to the wafer in the reaction chamber, the purge process 100 is carried out which includes steps 102, 104 and 106.

In step 102, an inert gas is channeled into the reaction chamber to purge the reaction chamber. The inert gas includes nitrogen, helium, argon or krypton, for example. And, a flow rate of the inert gas is such as from 50 SCCM to 150 SCCM. For instance, the step 120 is performed in the magnetic field of 30 G˜60 G and a temperature of 40° C.˜60° C. form 10 seconds to 30 seconds.

In step 104, all the gas inside the reaction chamber is exhausted. The step 104 is performed from seconds to 30 seconds and stopped until the pressure of the reaction chamber being less than 1 mill Torr, for example.

The steps 102 and 104 can be repeated. In this case, the step 102 is first done in the purge process 100. However, the sequence of the steps is without limits, such as the step 104 can be performed before the step 102.

Afterwards, the step 106 is optionally performed to bombard the wafer with inert gas plasma for further removing the byproducts caused by the dry etching process. The inert gas plasma includes argon plasma, for example. The subsequent process can be performed after finishing the purge process 100. Moreover, it is possible to do the step 106 before step 102 or 104.

The purge process of the present invention can effectively purge away the byproducts caused by the dry etching process, whereby keeping electrical properties of subsequently formed structure. Besides, there is no chemical reaction in the purge process of the present invention, and thus there is no change to the defined patterns by the dry etching process.

The present preferred embodiments are as examples of the present invention thereinafter. However, it is not limited to the application field of the present invention. The purge process of the present invention can be applied after all dry etching processes of metal interconnects in order to remove the byproducts caused by the dry processes.

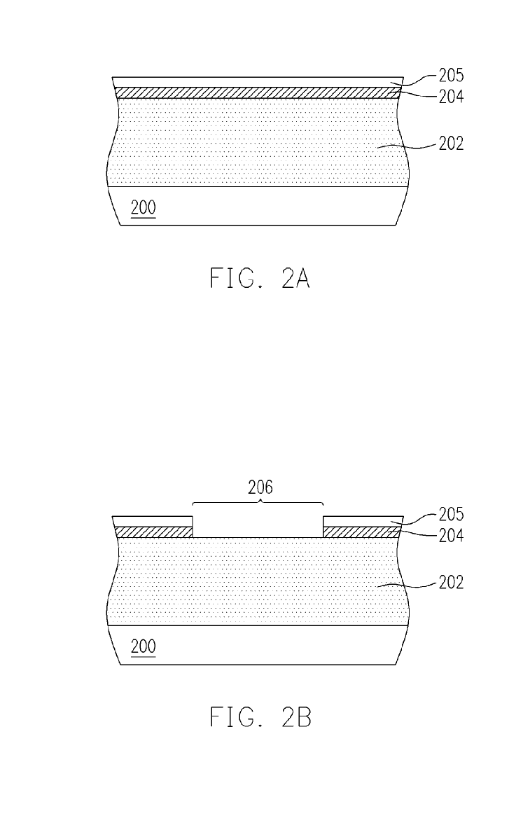

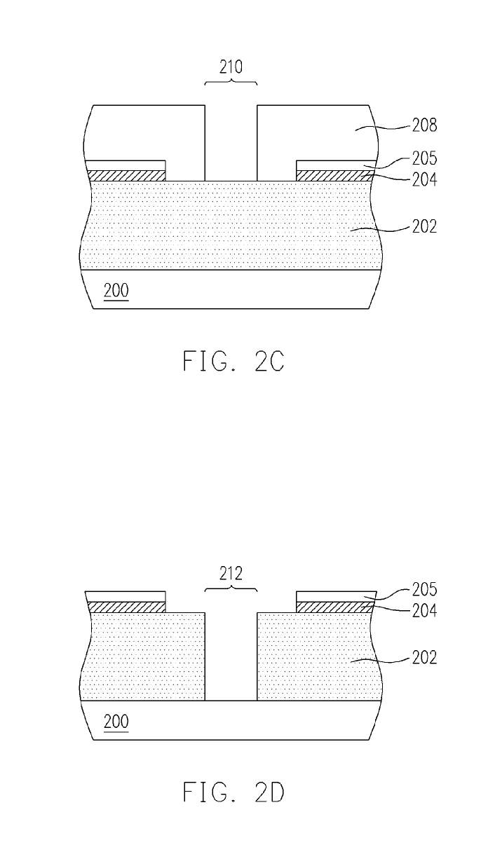

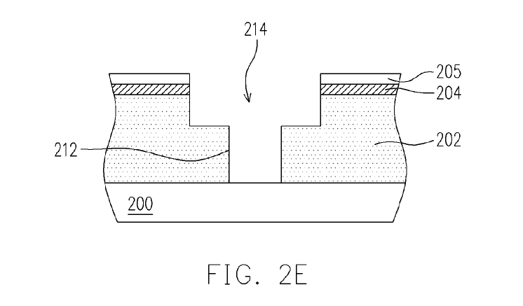

FIGS. 2A to 2E are schematic cross-sectional views showing the process of forming a dual damascene opening according to one embodiment of the present invention.

As shown in FIG. 2A, a substrate 200 is provided. The substrate 200 is a silicon substrate, for example. Then, a dielectric layer 202 is formed on the substrate 200. The dielectric layer 202 is made of silicon oxide or a silicon-based low dielectric constant material such as HSQ or MSQ, for example. Thereafter, a hard mask layer 204 is formed on the dielectric layer 202. The hard mask layer 204 is a metal hard mask layer made of titanium, titanium nitride, tantalum, tantalum nitride or tungsten nitride, for example. After that, an anti-reflection layer 205 is optionally formed on the hard mask layer 204. A material of the anti-reflection layer 205 is such as silicon oxynitride.

Then, as shown in FIG. 2B, a trench pattern 206 is formed by performing a dry etching process to the hard mask layer 204 inside a first reaction chamber (not shown). Thereafter, a first purge process is carried out to remove the byproducts formed in the dry etching process. The first purge process is carried out according to the actual requirements, and it is identical to the purge process 100 already described in FIG. 1. Hence, the detail is not repeated here.

Then, as shown in FIG. 2C, a patterned photoresist layer 208 is formed on the substrate 200 and it has an via opening pattern 210.

Afterward, as shown in FIG. 2D, another dry etching process is performed to the dielectric layer 202 inside a second reaction chamber (not shown) by using the patterned photoresist layer 208 (please refer to FIG. 2C) as a mask, thereby removing the dielectric layer 202 exposed by the via opening pattern 210 (please refer to FIG. 2C) and forming a via opening 212. Subsequently, the patterned photoresist layer 208 is removed. Thereafter, a second purge process is carried out to remove the byproducts formed in the foregoing dry etching process depending on circumstances. Furthermore, the second purge process is identical to the purge process 100 already described in FIG. 1. Hence, the detail is not repeated here.

As shown in FIG. 2E, another dry etching process is carried out to the dielectric layer 202 inside a third reaction chamber (not shown) by utilizing the hard mask layer 204 as a mask, thereby removing portion of the dielectric layer 202 exposed by the trench pattern 206 (please refer to FIG. 2B) and thus forming a trench 214 on the via opening 212. After the foregoing series of processes, a dual damascene opening that includes the trench 214 and the via opening 212 is formed. Thereafter, a third purge process is carried out to remove the byproducts formed in the above dry etching process. Furthermore, the third purge process is identical to the purge process 100 already described in FIG. 1. Hence, the detail is not repeated here.

Due to the fluorine-containing gas used in the plasma which used in the dry etching process, the byproducts such as titanium-fluorine oxide (TiₓF_{y}O_{z}) is formed by reaction between the hard mask layer and the fluorine-containing gas. This byproduct may produce some defects in the subsequently formed metal interconnects and lead to bridging problems that lowers the yield and reliability of the wafer. Therefore, the foregoing purge processes are performed in turn to remove various byproducts produced after each dry etching process. And, it can further prevent the electrical property of the metal interconnects in the dual damascene opening from error.

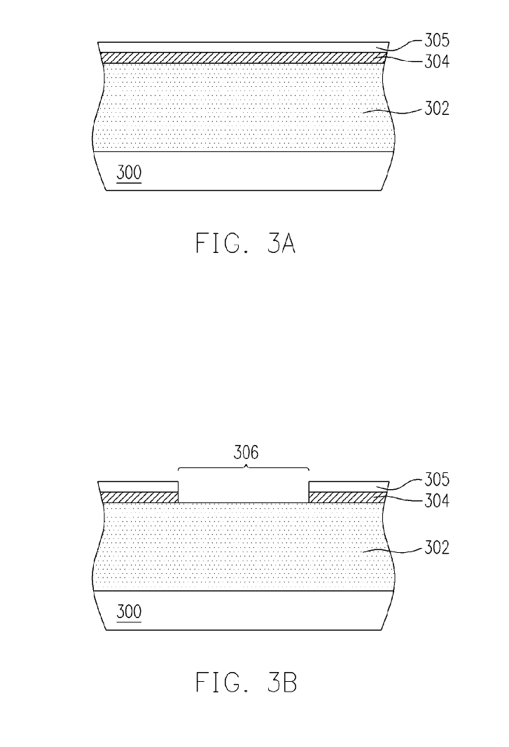

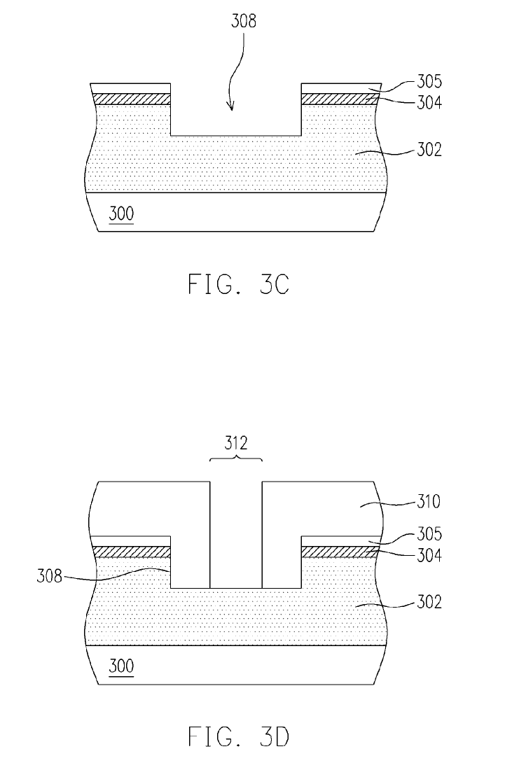

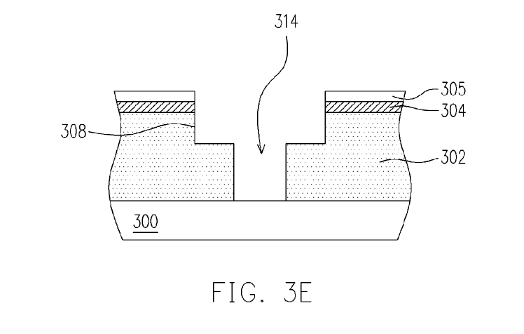

FIGS. 3A to 3E are schematic cross-sectional views showing the process of forming a dual damascene opening according to another embodiment of the present invention.

As shown in FIGS. 3A to 3B, the steps are the same as FIGS. 2A to 2B. a substrate 300 is provided. Then, a dielectric layer 302 and a hard mask layer 304 is formed on the substrate 300, sequentially. The hard mask layer 304 is a metal hard mask layer made of titanium, titanium nitride, tantalum, tantalum nitride or tungsten nitride, for example. After that, an anti-reflection layer 305 is optionally formed on the hard mask layer 304. Then, a trench pattern 306 is formed by performing a dry etching process to the hard mask layer 304 inside a first reaction chamber (not shown). Then, a first purge process is performed to remove the byproducts formed in the foregoing dry etching process.

As shown in FIG. 3C, another dry etching process is carried out to the dielectric layer 302 inside a second reaction chamber (not shown) by utilizing the hard mask layer 304 as a mask, thereby removing the dielectric layer 302 exposed by the trench pattern 306 (please refer to FIG. 3B) and thus forming a trench 308. Thereafter, a second purge process is performed to remove the byproducts formed in the etching process. The second purge process is identical to the purge process 100 in FIG. 1. Hence, a description of the purge process is omitted here.

As shown in FIG. 3D, a patterned photoresist layer 310 is formed on the substrate 300 and it has a via opening pattern 312 formed inside the trench 308.

As shown in FIG. 3E, another dry etching process is performed to the dielectric layer 302 inside a third reaction chamber (not shown) by using the patterned photoresist layer 310 (please refer to FIG. 3D) as a mask, thereby removing the dielectric layer 302 exposed by the via opening pattern 312 (please refer to FIG. 3D) and forming a via opening 314. Subsequently, the patterned photoresist layer 310 is removed. Afterward, a third purge process is performed to remove the byproducts formed in the dry etching process and it is identical to the purge process 100 already described in FIG. 1. Hence, the detail is not repeated here.

In summary, the purge process in the present invention can prevent any byproduct residues formed after an dry etching process from remaining inside the dual damascene opening to cause some non-uniformity in the electrical properties of subsequently formed metal interconnects and a drop in the yield.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A purge process after an etching process, wherein the dry etching process is carried out on a wafer inside a reaction chamber, and the purge process comprising:
a) channeling an inert gas into the reaction chamber to purge the reaction chamber; and
b) exhausting all the gas inside the reaction chamber;
wherein step (a) or step (b) can be carried out first, and step (a) and step (b) can be repeated to remove the byproducts formed after the dry etching process.

2. The purge process of claim 1, wherein the inert gas comprises nitrogen or helium.

3. The purge process of claim 1, wherein the process further comprises bombarding the wafer with inert gas plasma.

4. The purge process of claim 3, wherein the inert gas plasma comprises argon plasma.

5. A method of forming a dual damascene opening, comprising the steps of: providing a substrate;
forming a dielectric layer and a hard mask layer on the substrate, sequentially;
forming a trench pattern by performing a first dry etching process to the hard mask layer in a first reaction chamber;
performing a first purge process, wherein the first purge process including:
a) channeling a first inert gas into a first reaction chamber to purge the first reaction chamber; and
b) exhausting all the gas inside the first reaction chamber;
wherein the step (a) or step (b) can be performed first, and step (a) and step (b) can be repeated to remove the byproducts formed in the first dry etching process;
forming a patterned photoresist layer having a via opening pattern on the substrate; performing a second dry etching process to the dielectric layer in a second reaction chamber by using the patterned photoresist layer as a mask, thereby removing the dielectric layer exposed by the via opening pattern and forming a via opening;
removing the patterned photoresist layer;
performing a second purge process, wherein the second purge process including:
c) channeling a second inert gas into a second reaction chamber to purge the second reaction chamber; and
d) exhausting all the gas inside the second reaction chamber;
wherein the step (c) or step (d) can be performed first, and step (c) and step (d) can be repeated to remove the byproducts formed in the second dry etching process;
performing a third dry etching process to the dielectric layer in a third reaction chamber by utilizing the hard mask layer as a mask, thereby removing portion of the dielectric layer exposed by the trench pattern and forming a trench on the via opening; and
performing a third purge process, wherein the third purge process including:
e) channeling a third inert gas into a third reaction chamber to purge the third reaction chamber; and
f) exhausting all the gas inside the third reaction chamber;
wherein the step (e) or step (f) can be performed first, and step (e) and step (f) can be repeated to remove the byproducts formed in the third dry etching process.

6. The method of forming dual damascene opening of claim 5, wherein the first inert gas comprises nitrogen or helium.

7. The method of forming dual damascene opening of claim 5, wherein the second inert gas comprises nitrogen or helium.

8. The method of forming dual damascene opening of claim 5, wherein the third inert gas comprises nitrogen or helium.

9. The method of forming dual damascene opening of claim 5, wherein the first purge process further comprises bombarding the substrate with inert gas plasma.

10. The method of forming dual damascene opening of claim 9, wherein the inert gas plasma comprises argon plasma.

11. The method of forming dual damascene opening of claim 5, wherein the second purge process comprises bombarding the substrate with inert gas plasma.

12. The method of forming dual damascene opening of claim 11, wherein the inert gas plasma comprises argon plasma.

13. The method of forming dual damascene opening of claim 5, wherein the third purge process comprises bombarding the substrate with inert gas plasma.

14. The method of forming dual damascene opening of claim 13, wherein the inert gas plasma comprises argon plasma.

15. The method of forming dual damascene opening of claim 5, wherein the hard mask layer comprises a metal hard mask layer.

16. The method of forming dual damascene opening of claim 15, wherein the material constituting the metal hard mask layer is selected from a group consisting of titanium, titanium nitride, tantalum, tantalum nitride and tungsten nitride.

17. The method of forming dual damascene opening of claim 5, wherein after forming the hard mask layer but before forming the trench pattern, further comprises forming an anti-reflection layer on the hard mask layer.

18. The method of forming dual damascene opening of claim 17, wherein the material constituting the anti-reflection layer comprises silicon oxynitride.

19. A method of forming a dual damascene opening, comprising the steps of:
providing a substrate;
forming a dielectric layer and a hard mask layer on the substrate, sequentially;
forming a trench pattern by performing a first dry etching process to the hard mask layer in a first reaction chamber;
performing a first purge process, wherein the first purge process including:
a) channeling a first inert gas into a first reaction chamber to purge the first reaction chamber; and
b) exhausting all the gas inside the first reaction chamber;
wherein the step (a) or step (b) can be performed first, and step (a) and step (b) can be repeated to remove the byproducts formed in the first dry etching process;
performing a second etching process to the dielectric layer in a second reaction chamber by utilizing the hard mask layer as a mask, thereby removing the dielectric layer exposed by the trench pattern and forming a trench;
performing a second purge process, wherein the second purge process including:
c) channeling a second inert gas into a second reaction chamber to purge the second reaction chamber; and
d) exhausting all the gas inside the second reaction chamber;
wherein the step (c) or step (d) can be performed first, and step (c) and step (d) can be repeated to remove the byproducts formed in the second dry etching process;
forming a patterned photoresist layer on the substrate, wherein the patterned photoresist layer has a via opening pattern inside the trench;
performing a third dry etching process to the dielectric layer in a third reaction chamber by using the patterned photoresist layer as a mask, thereby removing the dielectric layer exposed by the via opening pattern and forming a via opening;
removing the patterned photoresist layer; and
performing a third purge process, wherein the third purge process including:
e) channeling a third inert gas into a third reaction chamber to purge the third reaction chamber; and
f) exhausting all the gas inside the third reaction chamber;
wherein the step (e) or step (f) can be performed first, and step (e) and step (f) can be repeated to remove the byproducts formed in the third dry etching process.

20. The method of forming dual damascene opening of claim 19, wherein the first inert gas comprises nitrogen or helium.

21. The method of forming dual damascene opening of claim 19, wherein the second inert gas comprises nitrogen or helium.

22. The method of forming dual damascene opening of claim 19, wherein the third inert gas comprises nitrogen or helium.

23. The method of forming dual damascene opening of claim 19, wherein the first purge process further comprises bombarding the substrate with inert gas plasma.

24. The method of forming dual damascene opening of claim 23, wherein the inert gas plasma comprises argon plasma.

25. The method of forming dual damascene opening of claim 19, wherein the second purge process comprises bombarding the substrate with inert gas plasma.

26. The method of forming dual damascene opening of claim 25, wherein the inert gas plasma comprises argon plasma.

27. The method of forming dual damascene opening of claim 19, wherein the third purge process comprises bombarding the substrate with inert gas plasma.

28. The method of forming dual damascene opening of claim 27, wherein the inert gas plasma comprises argon plasma.

29. The method of forming dual damascene opening of claim 19, wherein the hard mask layer comprises a metal hard mask layer.

30. The method of forming dual damascene opening of claim 29, wherein the material constituting the metal hard mask layer is selected from a group consisting of titanium, titanium nitride, tantalum, tantalum nitride and tungsten nitride.

31. The method of forming dual damascene opening of claim 19, wherein after forming the hard mask layer but before forming the trench pattern, further comprises forming an anti-reflection layer on the hard mask layer.

32. The method of forming dual damascene opening of claim 31, wherein the material constituting the anti-reflection layer comprises silicon oxynitride.
